(19) United States
(12) Patent Application Publication
(10) Pub. No.: US 2005/0230750 A1
(43) Pub. Date: Oct. 20, 2005

(54) Cathode substrate and its manufacturing method

(76) Inventors: Haruhisa Nakano, Ibaraki-ken (JP); Masaaki Hirakawa, Ibaraki-ken (JP); Osamu Miura, Ibaraki-ken (JP); Hirohiko Murakami, Ibaraki-ken (JP); Kensuke Okasaka, Saitama-ken (JP); Tomoaki Kojima, Saitama-ken (JP)

Correspondence Address: ARENT FOX PLLC, 1050 CONNECTICUT AVENUE, N.W., SUITE 400, WASHINGTON, DC, 20036, US

(21) Appl. No.: 11/066,562

(22) Filed: Feb. 28, 2005

(30) Foreign Application Priority Data
Mar. 1, 2004 (JP) 056624/2004

(51) Int. Cl. H01L 29/76

(52) U.S. Cl. 257/341

(57) ABSTRACT

A cathode substrate according to the present invention comprises a cathode electrode layer(12), insulator layer(14) and gate electrode layer(15) formed sequentially on a substrate to be processed (11). The insulator layer includes a hole (14a) formed there through. A gate aperture (16) is formed through the gate electrode layer. An emitter (E) is then provided at the bottom of the hole (14a). In this case, the gate aperture comprises a plurality of openings (16a), the total area of which is smaller than the area of top opening of the hole in the insulator layer. The openings are arranged densely at a position opposite to the emitter and just above the hole of the insulator layer.

### BACKGROUND OF THE INVENTION

1. Field of the Invention

The present invention relates to a cathode substrate which is suitably usable, for example, in a display having an electron emission source, and its manufacturing method. The present invention particularly relates to a cathode substrate suitable for use in a field emission display (FED) and which is formed of a carbon group emitter material such as graphite nanofibers or carbon nanotubes, and its manufacturing method.

2. Description of the Related Art

In recent years, there has been developed FED which utilizes an electron emission source formed of a carbon group emitter material such as graphite nanofiber or carbon nanotube, such a material having a lower electron emission voltage and a chemical stability. It is the mainstream that this FED makes use of a field emitter with a triode structure comprising a cathode electrode, a gate electrode and an anode electrode so that the necessary drive voltage to emit electrons can be reduced.

In such a case, it has been proposed that a cathode substrate is provided by sequentially forming a cathode electrode layer, insulator layer and gate electrode layer on a substrate to be processed, forming one gate aperture on the gate electrode layer, forming a hole through the gate aperture, said hole having its area of top opening larger than that of the gate aperture in the insulator layer, thereafter providing a catalyst layer at the bottom of the hole, and growing a carbon group emitter material to form an emitter on the catalyst layer.

However, the above prior art raises a problem in that, because only one gate aperture is located on the insulator layer opposite to the emitter, electrons will be drawn and accelerated from the emitter toward the gate electrode when the drive voltage is applied to the emitter to emit electrons. Thus, the emitted electrons will be diffused after passed through the gate aperture. The diffused electrons will deteriorate the efficiency of charge injection to an anode substrate (or electrode) which has been arranged opposite to the cathode substrate to form the field emitter with the triode structure.

Since the distance between the central part of the emitter and the gate electrode is different from that between the peripheral part of the emitter and the gate electrode, another problem is raised in that the efficiency of charge injection to the anode substrate will easily vary between each of emitters depending on the minute variation of the emitters in shape or size.

### SUMMARY OF THE INVENTION

In view of the above-described of the conventional art, this invention has an object of providing a cathode substrate which can prevent electrons emitted between each of emitters from being diffused to improve the efficiency of charge injection and which can also less vary the efficiency of charge injection between each of emitters, and its manufacturing method.

According to one aspect of this invention, there is provided a cathode substrate comprising: a cathode electrode layer formed on a substrate to be processed; a insulator layer formed on the cathode layer, said insulator layer including an emitter located at the bottom of a hole formed therein; and a gate electrode layer formed on the insulator layer, said gate electrode layer including a gate aperture formed therethrough, said gate aperture consisting of a plurality of openings, the total area of which is smaller than the area of top opening of the hole in said insulator layer, said openings being arranged densely at a position opposite to the emitter and just above the hole of the insulator layer.

In accordance with the present invention, the openings forming the gate aperture are arranged densely at a position opposite to the emitter and just above the hole of the insulator layer. Thus, when the drive voltage is applied to the emitter to emit electrons, they will be drawn and accelerated from the emitter just above. As a result, the emitted electrons will not be diffused after passed through the gate aperture in the gate electrode layer, and will be less influenced by the minute variation of the emitters in shape or size. In addition, the necessary drive voltage to emit the electrons can be held down in comparison to the prior art.

Preferably, the efficiency of charge injection to an anode substrate to be disposed opposite to said cathode substrate to form the field emitter with the triode structure is changed by increasing or decreasing at least one of the area of each opening and the number of openings.

Further, said emitter is formed of a carbon group emitter material and that the carbon group emitter material is grown on a catalyst layer.

According to another aspect of this invention, there is provided a cathode substrate manufacturing method comprises the steps of: forming a cathode electrode layer on a substrate to be processed; forming insulator layer on said cathode electrode layer; forming gate electrode layer on said insulator layer; providing a resist pattern on said gate electrode layer before the resist pattern and the gate electrode layer are etched to form a gate aperture consisting of a plurality of openings; etching said insulator layer through said gate aperture both in the directions of depth and width to form a single hole, the openings of said gate aperture being arranged densely at a position just above said hole; and providing an emitter at the bottom of the hole.

Preferably, said emitter is formed of a carbon group emitter material and that a catalyst layer acting as a catalyst as said carbon group emitter material is being grown is previously formed underside of said insulator layer.

On the other hand, said emitter is formed of a carbon group emitter material and that after the insulator layer has been etched, the catalyst layer acting as a catalyst as the carbon group emitter material is being grown is formed through the lift-off method and that a carbon group emitter is grown at the bottom of the hole through CVD method or a carbon group emitter is applied on the bottom of the hole through printing method.

As described above, according to this invention, there can be obtained an advantage in that the electrons emitted from the emitter will not be diffused to improve the efficiency of charge injection and also that the efficiency of charge injection will be less varied from one cathode substrate to another.

### BRIEF DESCRIPTION OF THE DRAWINGS

The above and other objects and the attendant features of this invention will become readily apparent by reference to the following detailed description when considered in conjunction with the accompanying drawings wherein:

FIG. 1 is a perspective view schematically illustrating a cathode substrate for FED according to the present invention.

FIGS. 2A through 2E illustrate a procedure for manufacturing a cathode substrate for FED according to the present invention.

FIG. 3 is a view illustrating a cathode substrate for FED according to the prior art.

FIGS. 4A and 4B show SEM illustrating a cathode substrate for FED manufactured according to the present invention.

FIGS. 5A and 5B show enlarged photographs which illustrate one pixel projected onto anode fluorescent substrates using cathode substrates in the Example 1 and comparative example 1.

FIGS. 6A through 6F illustrate a procedure for manufacturing another cathode substrate for FED according to the present invention.

### DETAILED DESCRIPTION OF THE PREFERRED EMBODIMENTS

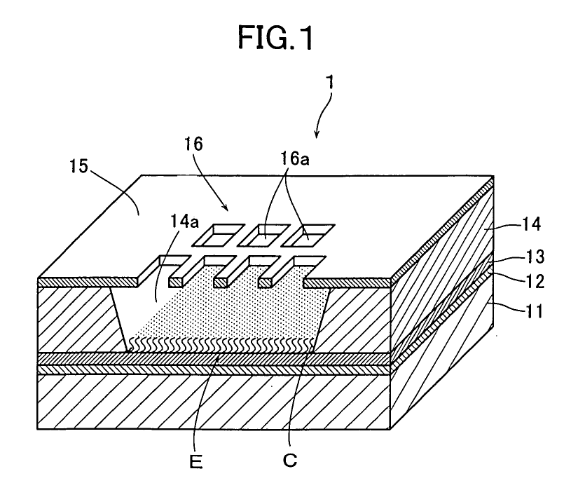

A description will now be made about a preferred embodiment of this invention with reference to the accompanying drawings. With Reference to FIG. 1, there is shown a cathode substrate 1 according to the present invention which may be used for FED. The cathode substrate 1 comprises a glass substrate 11 which is a substrate to be processed. A cathode electrode layer (bus) 12, for example, of chromium is formed on the surface of the glass substrate 11 with a predetermined film thickness. The cathode electrode layer 12 may be formed, for example, by DC sputtering while heating the glass substrate 11 to a predetermined temperature (e.g., 200 degrees Celsius).

A catalyst layer 13, for example, of a material selected from a group consisting of Fe, Co and alloys containing at least one of these metals is formed on the surface of the cathode electrode layer 12 with a predetermined film thickness (a range of 1-50 nm) and is then processed line-like. The catalyst layer 13 may be formed, for example, by DC sputtering. An emitter E is formed on the surface of this catalyst layer 13 by growing a carbon group emitter material C such as graphite nanofiber or carbon nanotube through any known process after a hole has been formed through an insulator layer as described later.

The insulator layer 14, for example, of SiO₂ is formed on the surface of the catalyst layer 13 with a predetermined film thickness (e.g., 3 μm). The insulator layer 14 may be formed, for example, by RF sputtering while heating the glass substrate 11 to a predetermined temperature (e.g., 300 degrees Celsius) for preventing damage due to stress in the formed insulator layer 14. This insulator layer 14 may be formed through several steps for preventing the formation of pinholes due to dust on the glass substrate 11 in the RF sputtering. Furthermore, the insulator layer 14 may be formed by any of EB and in-gas vapor depositions other than the aforementioned RF sputtering.

The insulator layer 14 also includes a hole 14a formed therethrough so that the catalyst layer 13 used to grow the carbon group emitter materials C will be exposed. With the insulator layer 14 of SiO₂, for example, the fluoric acid may be used as an etchant. The hydrofluoric acid is used to etch the insulator layer 14 to form the hole 14a having a predetermined section shape (e.g., circular).

In this case, after a plurality of openings forming a gate aperture have been formed through a gate electrode layer as described later, the insulator layer 14 is etched through each opening both in the directions of depth and width to form a single hole 14a below the gate electrode layer. These openings are arranged densely at a position opposite to the emitter E and just above the hole 14a of the insulator layer 14. At this time, the crosswise etching may be progressed if the over-etching time is controlled. In addition, the shape and/or size of the hole 14a in the insulator layer 14 may be selected depending on the number and/or layout of openings in the gate aperture.

The gate electrode layer 15, for example, of chromium is formed on the insulator layer 14 with a predetermined film thickness (e.g., 300 nm). The gate electrode layer 15 may be formed by DC sputtering while heating the substrate as in the cathode electrode layer 12. The gate electrode layer 15 includes a gate aperture 16 formed therethrough. The gate electrode layer 15 may be formed by any one of EB and in-gas vapor depositions other than the aforementioned RF sputtering.

If only a single gate aperture is provided at a position opposite to the emitter E and just above the hole 14a of the insulator layer 14 as in the prior art, and when the drive voltage is applied to the emitter electrons will be drawn and accelerated from the emitter E towards the gate electrode. Thus, the emitted electrons will be diffused after passed through the gate aperture. The diffused electrons will deteriorate the efficiency of charge injection to an anode substrate (not shown) which has been arranged opposite to the cathode substrate to form the field emitter with triode structure.

To overcome such a problem, the gate aperture 16 consists of a plurality of openings 16a, the total area of which is smaller than the area of top opening in the hole 14a on the insulator layer 14. These openings 16a are arranged densely and preferably densely and uniformly at a position opposite to the emitter E and just above the hole 14a of the insulator layer 14.

Each of the openings 16a is of substantially square or circular configuration, the length of one side or the diameter being between 1 μm and 3 μm. The spacing between the openings 16a adjacent to each other is ranged between 0.5 μm and 2 μm and the number of openings 16a is selected to be between 2 and 50. In this case, it is preferred that the total area of the openings 16a is between 50% and 90% of the area of top opening of the hole 14a in the insulator layer 14.

If the total area of the openings 16a is out of the range of 50-90% and too small, the efficiency of charge injection to the anode substrate will be deteriorated. On the other hand, if the total area is too large, the cathode substrate will be influenced by the diffusion of electrons and the minute variation of emitters from one emitter to another. It is also possible that the gate electrode will be deformed. Each of the openings 16a may be formed by transferring a predetermined resist pattern on the gate electrode layer 15 through the photolithography method and then etching it in wet or dry.

Thus, the electrons will be drawn and accelerated just above the emitter E when the drive voltage is applied to the emitter to emit the electrons. As a result, the emitted electrons will not be diffused after passed through the openings 16a of the gate aperture 16 in the gate electrode layer 15. In addition, the emission of electrons will be less influenced by the minute variation of emitters. In this case, the efficiency of charge injection to the anode substrate can be changed by increasing or decreasing either of the total area or number of openings 16a.

Although this embodiment has been described as to the cathode substrate 1 for FED, the present invention will not be limited to such a structure, but can provide the cathode substrate 1 which can broadly be utilized as a general electron emission source.

### EXAMPLE 1

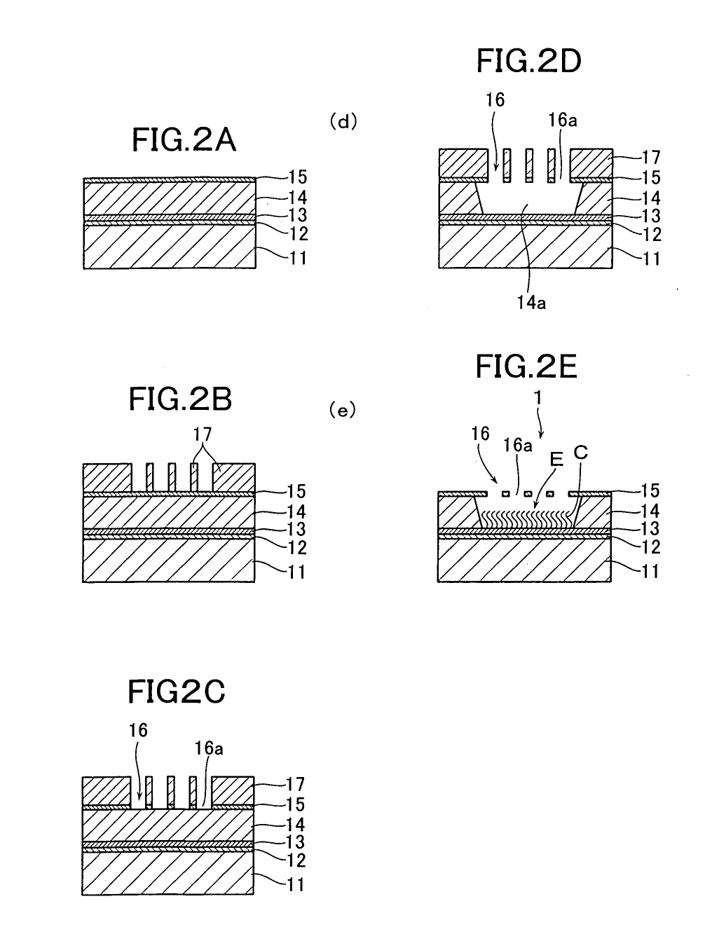

FIGS. 2A through 2E schematically illustrate various processes in a method of the present invention which can be carried out to make a cathode substrate 1 for FED according to the present invention.

As shown in FIG. 2A, a cathode electrode layer 12 of chromium was formed over a glass substrate 11 by DC sputtering while heating a glass substrate 11 to 200 degrees Celsius, the cathode electrode layer 12 having its film thickness of 100 nm. A catalyst layer 13 to be used for growing a carbon group emitter material of Fe alloy was then formed over the cathode electrode layer 12, the catalyst layer 13 having its film thickness of 25 nm.

An insulator layer 14 of SiO2 was then formed over the catalyst layer 13 by RF sputtering while heating the substrate to 375 degrees Celsius, the insulator layer 14 having its film thickness of 3 μm. Subsequently, a gate electrode layer 15 of chromium was formed over the insulator layer 14 by DC sputtering while heating the glass substrate 11 to 200 degrees Celsius, as in the cathode electrode layer 12. The gate electrode layer 15 had its film thickness of 300 nm.

As shown in FIG. 2B, a resist pattern 17 was then formed over the gate electrode layer 15 by photolithography method, the resist pattern 17 having its thickness of about 1 μm. As shown in FIG. 2C, a gate aperture 16 was then formed through the resist pattern 17 by etching. In this case, the resist material was one that was generally used in electron beam exposure apparatus. The gate aperture 16 included nineteen square-shaped openings 16a which were formed through the resist pattern 17 in a grid-like pattern by wet etching using a cerium sulfate ammonium solution. Also, each of the openings 16a was originally formed to have the length of each side equal to about 1 μm with the spacing between the adjacent openings 16a being equal to about 1 μm. Thereafter, the resist pattern 17 was over-etched to provide each opening 16a having the length of one side equal to about 1.2 μm and to provide the spacing between the adjacent openings 16a equal to 0.8 μm.

Subsequently, as shown in FIG. 2D, by utilizing the openings 16a of the gate aperture 16, the insulator layer 14 was wet-etched to form a single hole 14a of substantially circular configuration using fluoric acid as an etchant, so that the openings 16a were arranged densely at a position just above the hole 14a of the insulator layer 14. Thereafter, the resist pattern 17 was removed. At this time, the diameter of the top opening in the hole 14a was equal to about 16 μm. Subsequently, carbon nanotubes C were grown on the catalyst layer 13 through the openings 16a of the gate aperture 16 to form an emitter E by any suitable known method, as shown in FIG. 2E. Thus, the cathode substrate 1 was provided.

### COMPARATIVE EXAMPLE 1

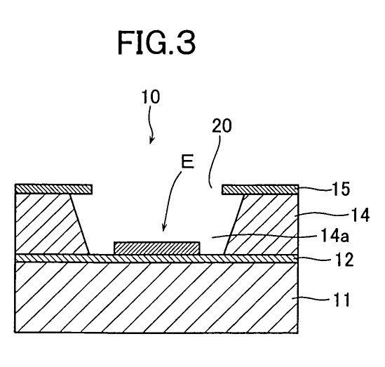

As a comparative example, a cathode electrode layer 12, catalyst layer, insulator layer 14 and gate electrode layer 15 were formed on a glass substrate 11 under the same conditions as in the above example 1, as shown in FIG. 3. Subsequently, a single gate aperture 20 was formed through the gate electrode layer 15 with the diameter thereof being equal to 10 μm, as in the above example 1. Thereafter, the insulator layer 14 was etched to form a hole 14a which had the diameter of top opening equal to about 16 μm. Carbon nanotubes were then grown on the catalyst layer to form an emitter E by any suitable known method. In this way, a cathode substrate 10 was provided.

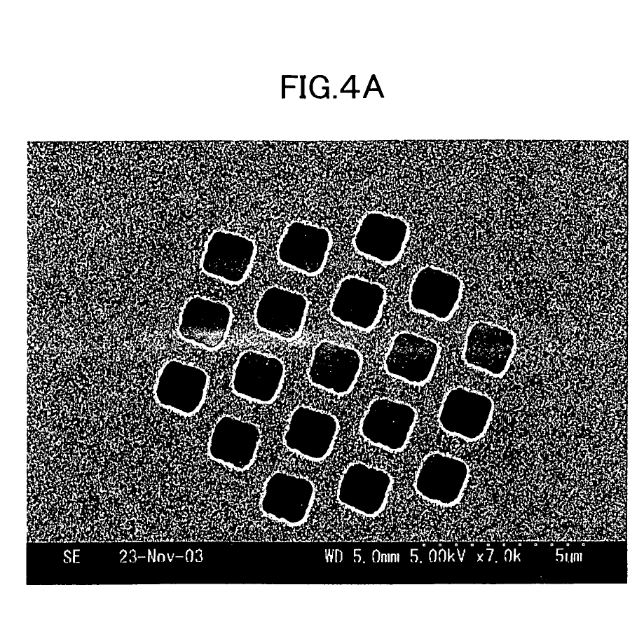

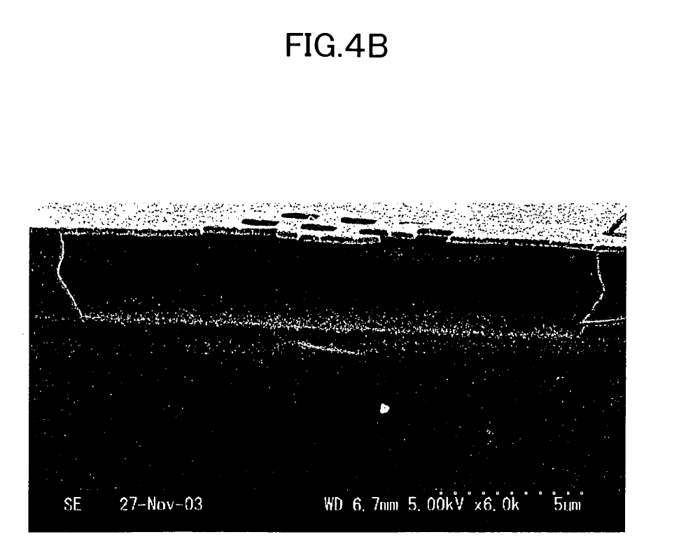

FIGS. 4A and 4B show SEM which illustrate the top face and cross-section of a cathode substrate 1 made according to the above procedure described in connection with Example 1. It is to be understood from these figures that a gate aperture 16 was formed through the insulator layer 14 to have a plurality of openings 16a with the total area and spacing as described above (see FIG. 4A). It is also to be understood that carbon nanotubes could be grown through the openings 16a (see FIG. 4B).

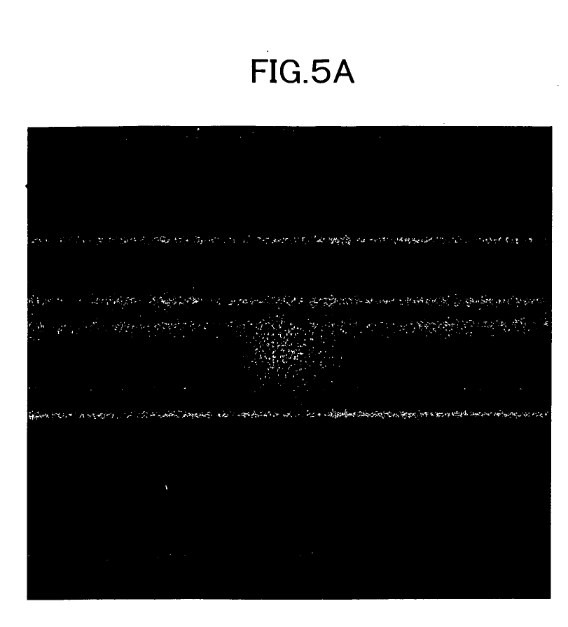

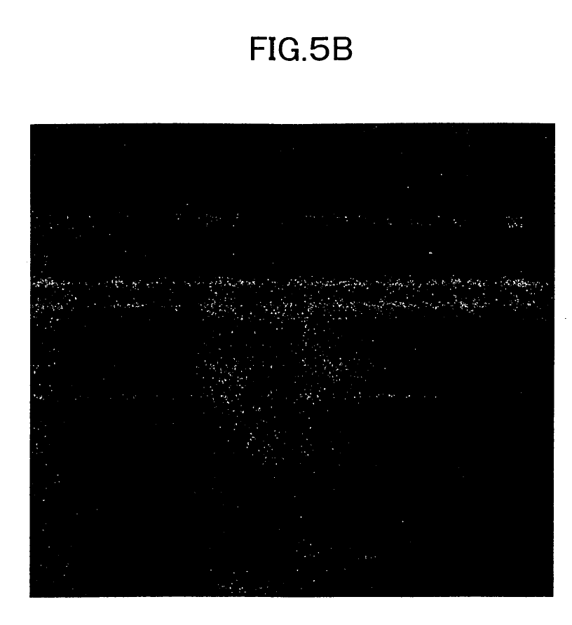

The comparative example 1 needed a drive voltage of about 60V to emit electrons, but the Example 1 required a drive voltage equal to about 20V. This indicates that the present invention can reduce the driving power. FIGS. 5A and 5B show enlarged photographs which illustrate one pixel projected onto anode fluorescent substances in connection with the structures of the Example 1 and comparative example 1, respectively. FIG. 5A relates to the Example 1, while FIG. 5B shows the comparative example 1. It is understood from this that the diffusion of electrons in the Example 1 could be reduced half of that in the comparative example 1.

### EXAMPLE 2

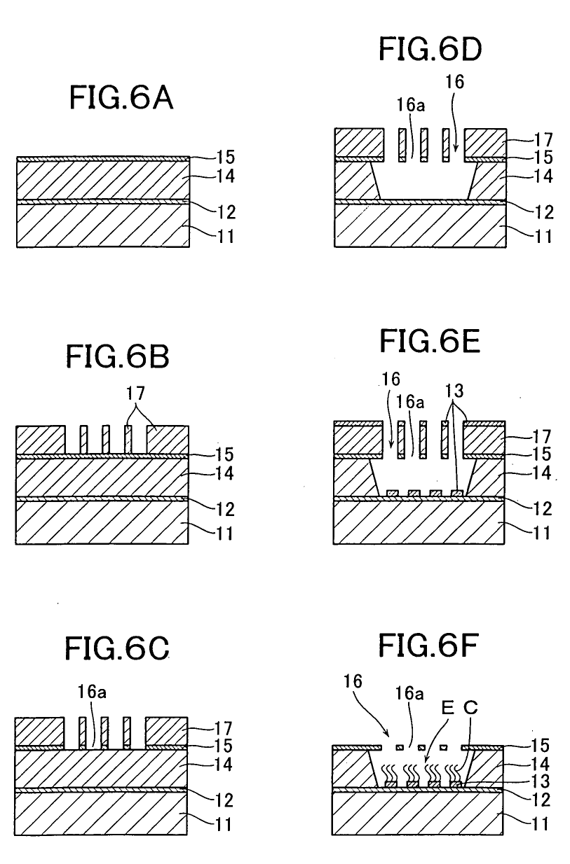

Example 2 is different from the above example 1 only in that a catalyst layer 13 is formed at the bottom of a hole 14a by RF sputtering method after an insulator layer 14 has been etched to form the hole 14a. Referring now to FIGS. 6A through 6F, an insulator layer 14 and gate electrode layer 15 were sequentially formed on a glass substrate 11 after a cathode electrode layer (bus) 12 has been provided on the glass substrate 11, in the same manner as in the above example 1 (see FIG. 6A).

Subsequently, a predetermined resist pattern 17 was transferred to the gate electrode layer 15 through photolithography method (see FIG. 6B), and the resist pattern 17 was then dry-etched to form a gate aperture 16 consisting of a plurality of openings 16a (see FIG. 6C). The insulator layer 14 was then wet-etched to form a single hole 14a (see FIG. 6D), and a catalyst layer 13 of carbon group emitter material was formed at the bottom of the hole 14a by RF sputtering method (see FIG. 6E), as in the above example 1. After the resist pattern 17 and the parts of the catalyst layer 13 deposited thereon had been removed, the carbon system material was grown on the catalyst layer 13 remaining on the bottom of the hole 14a to form an emitter E(see FIG. 6F).

Even in the cathode substrate 1 made according to such a procedure as described in this example 2, the catalyst layer could be formed through the openings 16a of the gate aperture 16 formed on the insulator layer 14 with the pre-selected total area and spacing of the openings 16a and the carbon nanotubes could be grown on the catalyst layer. As in the above example 1, the necessary drive voltage to emit electrons could be reduced while at the same time the electronic diffusion could be reduced.

1. A cathode substrate comprising:
a cathode electrode layer formed on a substrate to be processed;
a insulator layer formed on the cathode layer, said insulator layer including an emitter located at the bottom of a hole formed therein; and
a gate electrode layer formed on the insulator layer, said gate electrode layer including a gate aperture formed therethrough, said gate aperture consisting of a plurality of openings, the total area of which is smaller than the area of top opening of the hole in said insulator layer, said openings being arranged densely at a position opposite to the emitter and just above the hole of the insulator layer.

2. A cathode substrate according to claim 1, wherein the efficiency of charge injection to an anode substrate to be disposed opposite to said cathode substrate to form the field emitter with the triode structure is changed by increasing or decreasing at least one of the area of each opening and the number of openings.

3. A cathode substrate according to claim 1 or 2, wherein said emitter is formed of a carbon group emitter material and that the carbon group emitter material is grown on a catalyst layer.

4. A cathode substrate manufacturing method comprises the steps of:
forming a cathode electrode layer on a substrate to be processed;
forming insulator layer on said cathode electrode layer;
forming gate electrode layer on said insulator layer;
providing a resist pattern on said gate electrode layer before the resist pattern and the gate electrode layer are etched to form a gate aperture consisting of a plurality of openings;
etching said insulator layer through said gate aperture both in the directions of depth and width to form a single hole, the openings of said gate aperture being arranged densely at a position just above said hole; and
providing an emitter at the bottom of the hole.

5. A cathode substrate manufacturing method according to claim 4, wherein said emitter is formed of a carbon group emitter material and that a catalyst layer acting as a catalyst as said carbon group emitter material is being grown is previously formed underside of said insulator layer.

6. A cathode substrate manufacturing method according to claim 4, wherein said emitter is formed of a carbon group emitter material and that after the insulator layer has been etched, the catalyst layer acting as a catalyst as the carbon group emitter material is being grown is formed through the lift-off method and that a carbon group emitter is grown at the bottom of the hole through CVD method or a carbon group emitter is applied on the bottom of the hole through printing method.
